(19) United States
(12) Patent Application Publication
(10) Pub. No.: US 2005/0196942 A1
(43) Pub. Date: Sep. 8, 2005

(54) Protective tape for use in grinding back of semiconductor wafer and method of fabricating semiconductor device

(75) Inventors: Daichi Okada, Yokkaichi (JP); Masatoshi Kawato, Kameyama (JP); Shigetaka Oonishi, Yokkaichi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/065,060

(22) Filed: Feb. 25, 2005

(30) Foreign Application Priority Data
Feb. 26, 2004 (JP) 2004-051532

(51) Int. Cl. H01L 21/78

(52) U.S. Cl. 438/464

(57) ABSTRACT

A protective tape protecting a surface of a semiconductor wafer in a process of grinding a back of the wafer includes a layer of polyethylene terephthalate, an intermediate layer formed on the polyethylene terephthalate layer so as to have an elasticity modulus ranging from 20 MPa to 40 MPa, and an adhesive layer formed on the intermediate layer.

### CROSS-REFERENCE TO RELATED APPLICATION

This application claims priority to Japanese patent application No. 2004-51532, filed Feb. 26, 2004, the content of which is incorporated herein by reference.

### BACKGROUND OF THE INVENTION

1. Field of the Invention

The present invention relates to a protective tape applied to a back surface of a semiconductor wafer in back grinding, and a method of fabricating a semiconductor device.

2. Description of the Related Art

Semiconductor devices are manufactured through processes including front-end and back-end processes. In the front-end process, a circuit pattern is formed on a surface of a semiconductor wafer. Thereafter, grinding, dicing, wire bonding, packaging and the like are carried out for a back of the semiconductor wafer in the back-end process.

Semiconductor chips incorporated in the semiconductor devices have recently been required to be thinned. In the case of a semiconductor chip with a large diameter, a semiconductor wafer is required to be ground to the thickness of 50 to 100 μm or below in a back grinding process. Warp of a semiconductor wafer is increased with progress of the thinning. A three-layer tape composed of a polyethylene terephthalate layer, an intermediate layer and an adhesive layer is used as a protective tape for protecting a surface of the wafer against warp. This three-layer tape contains polyethylene terephthalate as a hard material.

Warp of a semiconductor wafer is increased when the intermediate layer of the protective tape has an excessively high elasticity modulus. In this case, there is a possibility that semiconductor wafers may be damaged or broken when conveyed by a conveyor. In view of this problem, JP-A-2003-129011 discloses a technique of suppressing the wafer warp. The disclosed technique uses a stress relaxation film to suppress the wafer warp.

FIG. 4 schematically illustrates a manner of using the aforementioned protective tape. Firstly, a circuit pattern is formed on a surface of a semiconductor wafer 1. For example, polyimide is then coated on an entire upper surface of the wafer 1 so as to be formed into a protective film 2 protecting a patterned face. The protective film 2 is etched so that a groove 3 is formed therein. The groove 3 is formed in order to separate semiconductor chips easily in a dicing process which is included in the back-end process.

Subsequently to the forming of the groove 3, a protective tape 4 is applied onto the protective film so as to cover the entire upper surface of the wafer 1. A back 1b of the wafer 1 is ground in a back grinding process. After a dicing tape is then transferred and the protective tape 4 is separated, the semiconductor chips are separated in the dicing process.

However, when the back 1b of the wafer 1 is ground by a grindstone in the back grinding process with the aforesaid protective tape 4 used, the semiconductor wafer 1 cracks, which reduces the yield. Even if the wafer 1 has no crack, a back flatness of thereof is reduced, which also reduces the yield.

The following may be considered as the reason for the reduction in the yield and/or back flatness: when the wafer back is ground by a grindstone in the back grinding process, a part of the surface 1a abuts against the protective tape 4 through the groove 3 formed in the protective film 2, whereupon a force is applied to an abutting portion 4a. The force is absorbed mainly into the intermediate layer 4b of the protective tape 4. However, when the pressure the grindstone applies is high and the intermediate layer 4b has an extremely low elasticity modulus, the wafer back 1b is ground while a part of the wafer surface 1a is deformed so as to subside relative to the protective tape 4, as shown in FIG. 4. When the wafer back 1a is thus ground in the aforementioned deformed state, crack starting at the groove 3 occurs in the wafer 1. The yield is considered to be reduced for the above-described reason.

Furthermore, even if the wafer 1 has no crack, force is transferred from the wafer surface 1a side to act on the back 1b side when the back grinding process is finished and the grindstone 5 is parted from the wafer 1. The force causes an irregularity 6 in the back 1b as shown in FIG. 5, whereupon the back flatness H would be reduced. More specifically, even when the stress relaxation film with a more suitable relaxation modulus (for example, not less than 40%, 50%, 60%, 99% or 99.9% or theoretically 100%) is used as shown in JP-A-2003-129011, an amount of subsidence of the wafer surface 1a in the back grinding process is increased such that crack occurs in the wafer 1. Moreover, even if no crack occurs, force is transferred from the wafer surface 1a side to be applied to the back 1b side is increased, whereupon the back flatness is reduced.

### BRIEF SUMMARY OF THE INVENTION

Therefore, an object of the present invention is to provide a protective tape which can suppress an amount of warp of the semiconductor wafer and reduction in the yield resulting from the groove formed in the protective film on the wafer surface and reduction in the back flatness of the wafer, and a method of fabricating a semiconductor device utilizing the protective tape.

The present invention provides a protective tape protecting a surface of a semiconductor wafer in a process of grinding a back of the wafer, the protective tape comprising a layer of polyethylene terephthalate, an intermediate layer formed on the polyethylene terephthalate layer so as to have an elasticity modulus ranging from 20 MPa to 40 MPa, and an adhesive layer formed on the intermediate layer.

The invention also provides a method of fabricating a semiconductor device comprising applying a three-layer protective tape to a surface of a semiconductor wafer on which a circuit pattern is formed, the three-layer protective tape including a layer of polyethylene terephthalate, an intermediate layer formed on the polyethylene terephthalate layer so as to have an elasticity modulus ranging from 20 MPa to 40 MPa, and an adhesive layer formed on the intermediate layer, grinding a back of the semiconductor wafer, and separating a chip from the wafer whose back has been ground.

### BRIEF DESCRIPTION OF THE DRAWINGS

Other objects, advantages and features of the present invention will become clear upon reviewing the following description of the embodiment with reference to the accompanying drawings, in which:

FIG. 1A is a perspective view of a protective tape of one embodiment in accordance with the present invention, showing a manner of using the protective tape;

FIG. 1B illustrates a back grinding process;

FIGS. 2A to 2D are graphs showing measurements of the back near a groove of a protective film;

FIG. 3 is a graph showing an amount of warp, elasticity modulus dependency of back flatness;

FIG. 4 schematically illustrates a manner of using a conventional protective tape; and

FIG. 5 illustrates an irregularity formed in a back of a conventional semiconductor wafer.

### DETAILED DESCRIPTION OF THE INVENTION

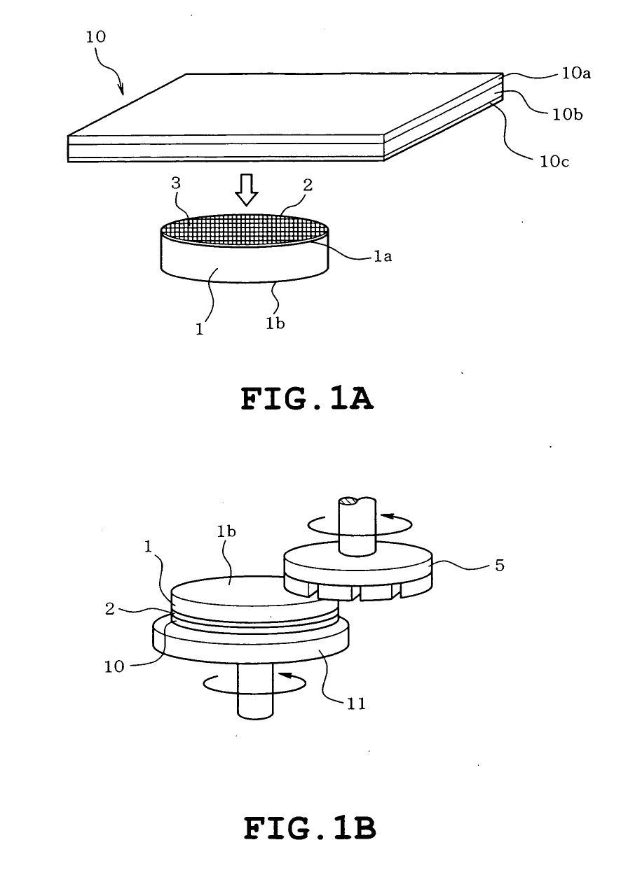

One embodiment of the present invention will be described with reference to FIGS. 1A to 3. The invention is applied to grinding a back of a bumpless semiconductor wafer in the embodiment. In the following, identical or similar parts are labeled by the same reference symbols as those in the description of the related art and the differences form the related art will mainly be described.

The embodiment has a characteristic particularly in a back grinding process in an assembly step carried out after a circuit pattern has been formed on a surface 1a of a semiconductor wafer 1. The characteristic will mainly be described in the following. As shown in FIG. 1A, after the circuit pattern has been formed on the surface 1a of the semiconductor wafer 1, the formed circuit pattern is inspected. The assembly step is carried out upon completion of the inspection step.

The assembly step includes a back grinding process of grinding a back of the semiconductor wafer 1, a dicing process of separating chips from the semiconductor wafer 1, a die-bonding process of picking up and mounting the chips on a lead frame, a wire bonding process of connecting electrode terminals of each chip to inner lead of the lead frame using gold wire so that a section therebetween is electrically conductive, and the like. The back of the wafer 1 is ground in the back grinding process. A protective tape 10 as shown in FIG. 1A is used in the back grinding process. FIG. 1A shows a schematic structure of the protective tape 10.

A usage of the protective tape 10 will be described with reference to FIGS. 1A and 1B. The circuit pattern (not shown) is formed on the surface 1a of the wafer 1 and thereafter, a protective film 2 is formed on the surface 1a of the wafer 1. The protective film 2 comprises a polyimide film (PI film) and has a film thickness of about 5 μm. The protective film 2 is used to protect the circuit pattern. Subsequently, the protective film 2 is etched so that a groove 3 is formed. The groove 3 is indicative of a linear boundary line and has a width (lateral dimension as viewed in FIG. 1A) set at about 100 μm, for example.

The protective tape 10 is applied to an entire surface 1a of the wafer 1 after the protective film 2 has been etched and the groove 3 has been formed in the wafer 1. The structure of the protective tape 10 is shown in FIG. 1A. The protective tape 10 has a three-layer structure. More specifically, the protective film 10 includes a polyethylene terephthalate (PET) layer 10a, an intermediate layer 10b formed on the PET layer 10a and an adhesive layer 10c formed on the intermediate layer 10b. The adhesive layer 10c is made of an acrylic material and is applied to the polyimide (PI) film 2.

After the protective film 10 has been applied to the PI film 2, the back of the wafer 1 is fixed onto a turntable 11 while the back 1b of the wafer 1 is turned upside with the PET layer 10a being located underside. The back 1a of the wafer 1 is ground by the grindstone 5 while the turntable 11 is being turned. The wafer 1 has a diameter of 200 mm and a thickness of 725 μm±25 μm before the grinding. The back 1a of the wafer 1 is ground until the thickness is reduced below 85 μm (for example, 50 μm) as shown in FIG. 1B.

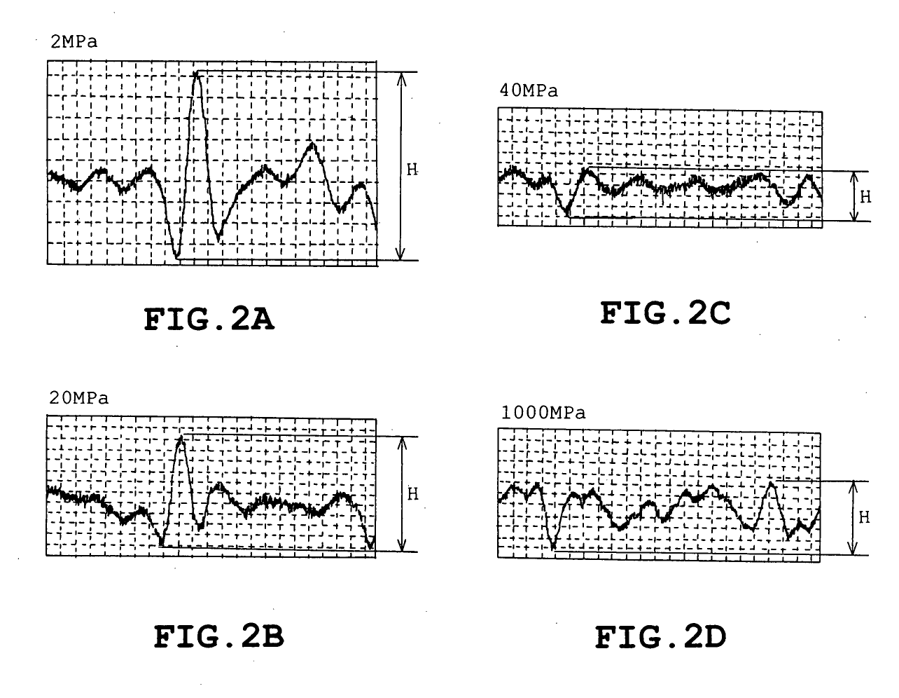

FIGS. 2A to 2D show back flatness measured near the groove 3 after the back grinding with use of the protective tape 10 having the conditions as shown in TABLE 1. These experimental results were obtained from the irregularity of wafer back 1b.

TABLE 1

| | Thickness of | | Thickness | Thickness |
|---|---|---|---|---|
| | intermediate | Elastic | of | of adhesive |
| | layer | modulus | PET | layer |
| No. 1 | 105 μm | 2 MPa | 75 μm | 30 μm |
| No. 2 | 105 μm | 20 MPa | 75 μm | 30 μm |
| No. 3 | 150 μm | 40 MPa | 50 μm | 30 μm |
| No. 4 | 0 μm | 1000 MPa | 50 μm | 30 μm |

Regarding the elasticity modulus, both ends of a tensile test strip made of a material used for the intermediate layer 10b (the PET layer 10a for No. 4) were drawn under predetermined pinching conditions. Displacement and strength were measured, and TABLE 1 shows an elasticity modulus in tension obtained on the basis of the measured displacement and strength. Under condition No. 4, a two-layer tape composed of PET layer 10a and the adhesive layer 10c without the intermediate layer 10b was used. In this case, a thickness of the intermediate layer 10b is shown as 0 and the elasticity modulus shown as 1000 MPa is that of the PET layer 10a.

The three-layer protective tape 10 includes the intermediate layer 10b having a practical thickness range from 30 to 200 μm. However, more preferable results can be achieved from the protective tapes 10 with the intermediate layers 10b having the condition Nos. 1 to 3 in TABLE 1 respectively.

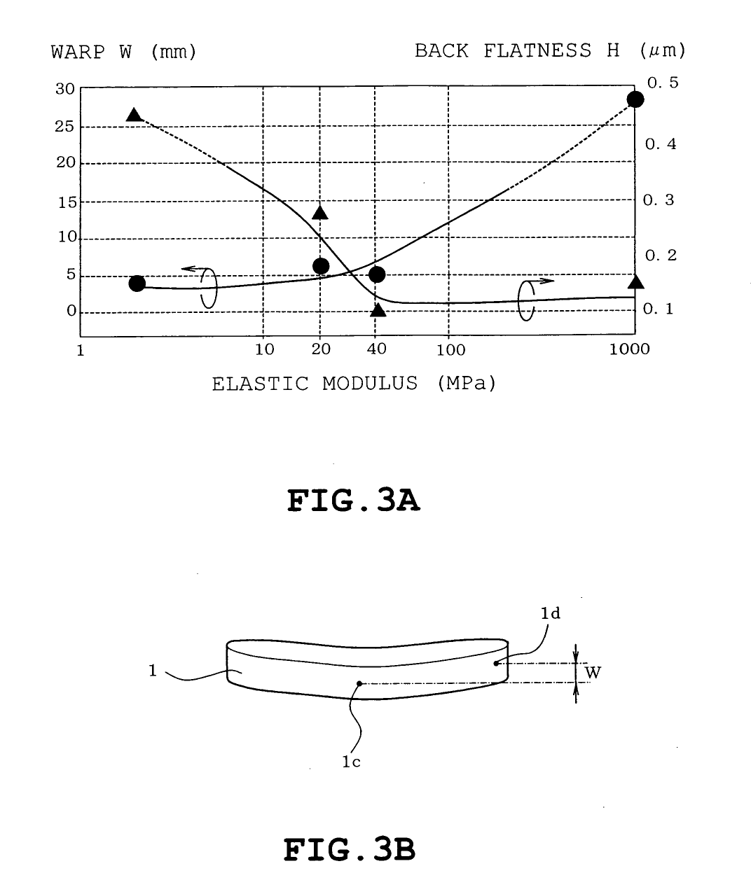

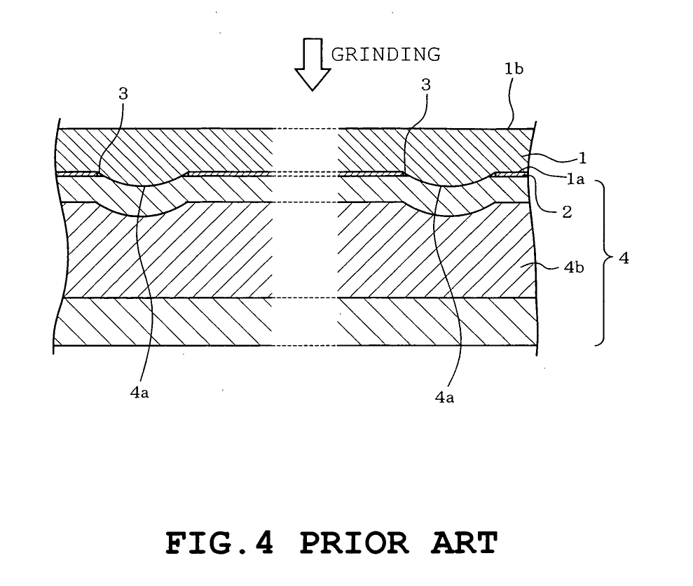

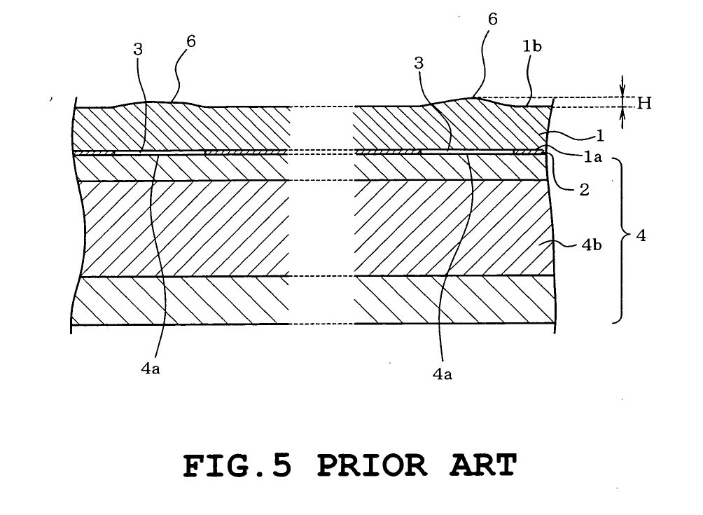

FIG. 3A shows dependency of back flatness H and warp amount W on the elasticity modulus when the back flatness is defined as the difference between maximum and minimum detected values of irregularity 6 of the wafer 1 near the groove 3. The semiconductor wafer 1 warps spherically after the back grinding process as shown in FIG. 3B. FIG. 3A shows the value of warp W occurred between the center 1c and end 1d of the wafer 1.

FIGS. 2A to 2D show back flatness values measured after back grinding with use of the protective tapes 10 made under the condition Nos. 1 to 4 respectively. Under condition No. 1, the back flatness H of the wafer 1 is about 0.454 μmp-p. Under condition No. 2, the back flatness H of the wafer 1 is about 0.275 μmp-p. Under condition No. 3, the back flatness H of the wafer 1 is about 0.10 μmp-p. Under condition No. 4, the back flatness H of the wafer 1 is about 0.15 μmp-p.

The back flatness H depends largely upon the state of the protective film 2 near the protective film 2 as shown in FIG. 3A. Furthermore, the back flatness H becomes worse as the elasticity modulus of the intermediate layer 10b is small. The reason for this is as follows: a part of the surface 1a abuts against the protective sheet 10 through the groove 3 formed in the protective film 2, as described above. The wafer back 1b is ground while a part of the wafer surface 1a is deformed so as to subside relative to the protective sheet 10. Upon finish of the back grinding process, force is transferred from the wafer surface 1a side to act on the back 1b side, thereby causing irregular portions 6 near the groove 3. This may be considered a reason for the aforementioned dependency of the back flatness upon the state of the protective film 2 near the groove 3 and the aforementioned worsening of the back flatness.

However, as shown in FIGS. 2C and 2D, the back flatness H can be suppressed within a range of measurement error under the condition of increased elasticity modulus of the intermediate layer 10b. More specifically, it is preferable to increase the elasticity modulus of the intermediate layer 10b to or above 20 MPa and further preferable to increase the elasticity modulus of the intermediate layer 10b to or above 40 MPa.

Furthermore, as shown in FIG. 3A, the warp W is about 4 mm under condition No. 1, about 6 mm under condition No. 2, about 4.8 mm under condition No. 3, and about 28 mm under condition No. 4. In view of measurement error, a preferable result of warp W can be obtained when the elasticity modulus of the intermediate layer 10b set to be not more than 20 or 40 MPa. Accordingly, the warp W can be suppressed when the wafer back is ground while the protective tape 10 applied to the surface of the wafer 1 includes the intermediate layer 10b with the elasticity modulus ranging from 20 to 40 MPa. Consequently, the back flatness H of the wafer 1 can be rendered desirable and accordingly, a desired grinding can be achieved.

Subsequently to the grinding of the wafer back, the back 1b of the wafer 1 is transcribed to a dicing tape (not shown). The dicing tape is used to transcribe and divide the wafer back 1b to the chips in the dicing process. After the dicing tape has been applied to the wafer back 1b, the protective tape 10 applied to the surface 1a of the wafer 1 is removed, whereupon the individual chips can be removed in the dicing process.

When the back of a semiconductor wafer formed with bumps is to be ground, the used intermediate layer 10b has an elasticity modulus ranging from 1 to 10 MPa. The following is a case where the used three-layer protective tape has an extremely high elasticity modulus exceeding 10 MPa. In this case, when the protective tape is applied to the surface 1a of the wafer 1 with bumps and the wafer back is ground, a repulsive force caused by the surface protective tape is concentrated on the bumps according to the conditions in the back grinding. As a result, there is a possibility that bumps may be damaged and/or the wafer may be cracked. The invention may be applied to a fabrication process in which semiconductor chips are separated in a dicing process and thereafter, bumps are formed on the semiconductor chips.

As obvious from the foregoing, the protective tape comprises the three layers, that is, the PET layer 10a, the intermediate layer 10b and the adhesive layer 10c. The intermediate layer 10b has an elasticity modulus ranging from 20 to 40 MPa. Consequently, an amount of warp of the semiconductor wafer 1 can be suppressed even when the bumpless semiconductor wafer is thinned, reduction in the yield caused by the groove 3 of the protective film 2 can be suppressed, whereupon both of the warp W and back flatness H of the wafer 1 can be improved.

The foregoing description and drawings are merely illustrative of the principles of the present invention and are not to be construed in a limiting sense. Various changes and modifications will become apparent to those of ordinary skill in the art. All such changes and modifications are seen to fall within the scope of the invention as defined by the appended claims.

1. A protective tape protecting a surface of a semiconductor wafer in a process of grinding a back of the wafer, the protective tape comprising:
a layer of polyethylene terephthalate;
an intermediate layer formed on the polyethylene terephthalate layer so as to have an elasticity modulus ranging from 20 MPa to 40 MPa; and
an adhesive layer formed on the intermediate layer.

2. The protective tape according to claim 1, which is applied to grinding a back of a bumpless semiconductor wafer.

3. A method of fabricating a semiconductor device comprising:
applying a three-layer protective tape to a surface of a semiconductor wafer on which a circuit pattern is formed, the three-layer protective tape including a layer of polyethylene terephthalate, an intermediate layer formed on the polyethylene terephthalate layer so as to have an elasticity modulus ranging from 20 MPa to 40 MPa, and an adhesive layer formed on the intermediate layer;
grinding a back of the semiconductor wafer; and
separating a chip from the wafer whose back has been ground.
